(19) United States
(12) Patent Application Publication
(10) Pub. No.: US 2005/0145924 A1
(43) Pub. Date: Jul. 7, 2005

(54) Source/drain adjust implant

(76) Inventors: I-Sheng Liu, San Jose, CA (US); Shang-De Ted Chang, Fremont, CA (US)

Correspondence Address: Jon W. Hallman;MacPHERSON KWOK CHEN & HEID LLP, Suite 226, 1762 Technology Drive, San Jose, CA, 95110, US

(21) Appl. No.: 10/753,673

(22) Filed: Jan. 7, 2004

(51) Int. Cl. H01L 29/76; H01L 21/8238

(52) U.S. Cl. 257/315; 438/201; 438/211; 257/318; 438/262

(57) ABSTRACT

A two-transistor PMOS memory cell includes a PMOS floating gate transistor sharing a drain/source P+ diffusion region with a PMOS select gate transistor. The shared drain/source diffusion region acts as a drain for the floating gate transistor and as a source to the select gate transistor. The shared drain/source P+ diffusion region is formed in an N− well. Underlying the drain/source P+ diffusion region is a N implant having the same lateral extent of the drain/source P+ diffusion region to provide a lower programming voltage for the floating gate transistor and improved punch-through resistance for the select gate transistor.

### FIELD OF INVENTION

This invention relates generally to memory cells, and more particularly to a two-transistor PMOS memory cell.

### BACKGROUND

As compared to NMOS floating gate (FG) memory cells, PMOS FG memory cells have desirable band-to-band tunneling (BTBT) programming efficiencies. But memory arrays comprised of single transistor PMOS FG memory cells may suffer from problems such as over-erase and BTBT program disturbance, thereby compromising data integrity. As disclosed in commonly-assigned U.S. Pat. No. 5,912,842, the BTBT disturb problem may be solved by constructing memory arrays with two-transistor (2T) PMOS memory cells.

Although the 2T PMOS memory cells disclosed in U.S. Pat. No. 5,912,842 offer superior BTBT disturb resistance, problems arise as transistor dimensions continue to shrink into the deep submicron region. For example, the 2T PMOS memory cell includes an enhancement-type MOSFET. As such, the gate-to-source voltage must be sufficiently negative (or equivalently, the source-to-gate voltage being sufficiently positive) to attract holes into the n-type substrate such that an appreciable current will flow between the source and drain when a positive potential between source and drain is applied. This positive source-to-gate voltage sufficient to allow an appreciable current to flow may be denoted as the threshold voltage (V_{T}). It is desirable to keep V_{T} relatively low to achieve an efficient design. In an enhancement-type device such as the 2T PMOS cell, one way to achieve a low V_{T} is to keep the channel lightly doped. However, this light channel doping exacerbates the problem of punch-through. Punch-through occurs when a depleted region extends across the channel between source and drain, making the channel conductive under inappropriate conditions. Lightly doping the channel increases the dimensions of the depleted region. As the channel is made smaller and smaller as designs extend into the deep sub-micron region, the relative size of the depletion region thus becomes larger and larger with respect to the channel length.

Shrinking the dimensions of a 2T PMOS memory cell not only exacerbates the problem of punch-through, it also makes the programming of the floating gate (FG) transistor more difficult. In general, the voltage levels used in transistors should decrease as the size of the transistors is diminished. However, to achieve BTBT programming of the floating gate, relatively high voltages must be used, typically on the order of 9 volts or greater.

Accordingly, there is a need in the art for a 2T PMOS memory cell that provides more efficient BTBT programming and better punch-through resistance.

### SUMMARY

In accordance with one aspect of the invention, a 2T PMOS memory cell includes a PMOS select transistor having a drain and a source formed as separate P+ diffusion regions in an N− well; a PMOS floating gate transistor having a drain and a source formed as separate P+ diffusion regions in the N-well, wherein the P+ diffusion region that forms the floating gate transistor's drain is the same P+ diffusion region that forms the select gate transistor's source; and an N region underlying the P+ diffusion region that forms the floating gate transistor's drain. The N region underlying the P+ diffusion region decreases the resulting size of the depletion region so that programming efficiency in the floating gate transistor and punch-through resistance in the select gate transistor are both improved. However, because the N region shares the same lateral extent as the P+ diffusion region it underlies, the threshold voltages for the adjacent channels are not adversely affected.

### BRIEF DESCRIPTION OF THE DRAWINGS

FIG. 1 is a cross-sectional view of a PMOS 2T memory cell according to one embodiment of the invention.

FIG. 2 is a schematic view of a 2T cell array according to one embodiment of the invention.

FIG. 3 is a cross-sectional view of a 2T PMOS memory cell having a single polysilicon layer according to one embodiment of the invention.

### DETAILED DESCRIPTION

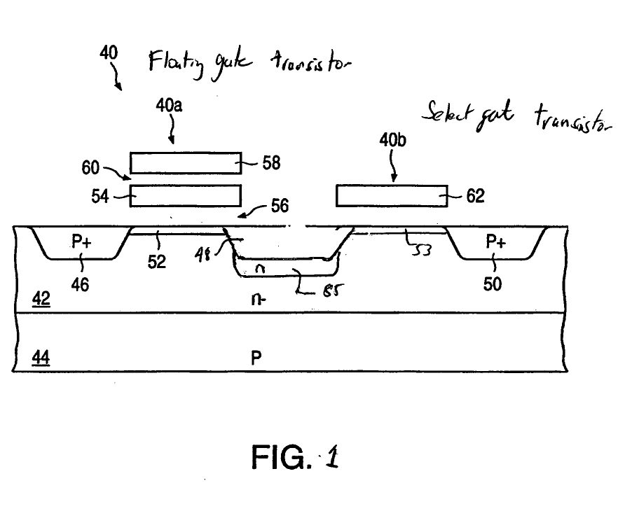

FIG. 1 illustrates a 2T PMOS memory cell 40. The two transistors in cell 40 are a floating gate (FG) PMOS transistor 40a and a PMOS select gate (SG) transistor 40b formed in an n-well region 42 of a p− substrate 44. A first p+ diffusion region 46 serves as a source 46 of FG transistor 40a. A second p+ diffusion region 48 serves as both a drain for FG transistor 40a and as a source for SG transistor 40b. As such, p+ diffusion region 48 may be denoted as a drain/source region 48. A third p+ diffusion region 50 serves as the drain for SG transistor 40b.

A tunnel oxide layer 56 having a thickness of, for example, between approximately 80 and 130′ separates a floating gate 54 for FG transistor 40a from n-well region 42. When floating gate 54 is negatively charged with respect to n-well region 42, a hole-containing channel region 52 is induced in n-well region 42. A similar channel region 53 may be induced for SG transistor 40b so that it functions as an enhancement-type transistor.

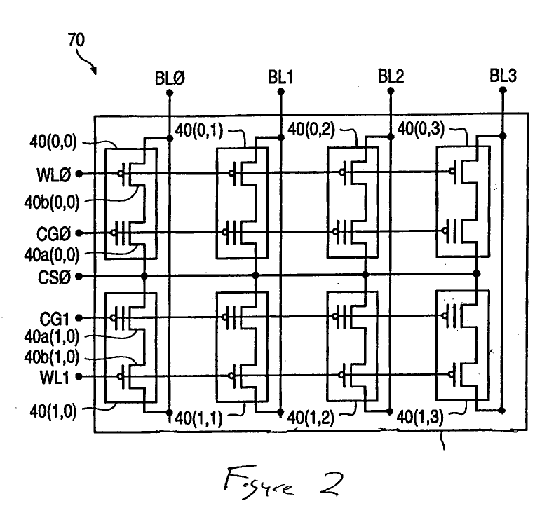

To program memory cell 40, hot electrons are introduced into floating gate 54 by either band-to-band tunneling (BTBT) or avalanche breakdown tunneling. Alternatively, a combination of the two tunneling processes or Fowler Nordheim tunneling may be used to program cell 40. For one embodiment, a programming technique may be discussed in conjunction with an array 70 of such memory cells 40(0,0) through 40(1,3) as seen in FIG. 2. For example, consider memory cell 40(0,0), which has a bit line BL0 coupling to drain 50 for SG transistor 40b(0,0). Also coupling to SG transistor 40b(0,0) of memory cell 40(0,0) is a word line WL0, which couples to select gate 62 of this cell. The bit line BL0 defines a column of memory cells 40 within the array 70. Similarly, the word line WL0 defines a row of memory cells 40 within the array. While n-well region 42(0) is kept at VCC, bit line BL0 is pulled down in potential and word line WL0 brought sufficiently negative so that the negative potential on bit line BL0 couples through SG transistor 40b to bring down the potential of drain 48 for FG transistor 40a. A depletion region will thus exist at the interface between n-well 42 and drain/source 48. To induce hot electron injection, control source line CS0, which couples to the sources 46 of memory cells 40 in the same row as WL0, is allowed to float while control gate line CG0, which couples to the control gates 58 in the same row, is pulsed with a positive voltage so that memory cell 40(0,0) is programmed. Note that the negative potential on bit line BL0 will also couple to other memory cells 40 in the same column. However, these other memory cells 40 will not couple to the same word line WL0. Thus, the SG transistors 40b in these other cells may be kept nonconductive to prevent the negative voltage on bit line BL0 from coupling to the associated drains 48 in these other memory cells 40. Analogous to the bit line, the programmed word line WL0 couples to other memory cells 40 in the same row. However, the bit lines coupling to these other memory cells on the can either float or be tied to VCC so that the associated drains 48 in these memory cells will not induce any hot electrons to enter the associated floating gates 54. Thus, an array of 2T memory cells 40 will not suffer any BTBT disturb during programming.

The presence of the injected electrons into floating gate 54 attracts holes into channel region 52 such that a programmed FG transistor 40a operates as a depletion-type transistor. Unlike an enhancement-type transistor, a depletion-type transistor is nominally in the conductive state and the threshold voltage for the gate/source potential determines when the device is non-conductive. To make channel region 52 non-conductive, the voltage potential on control gate 58 must be made positive with respect to source 46 to deplete the holes within channel 52. Thus, a programmed FG transistor 40a will be conductive when its control gate voltage is below a positive threshold voltage whereas a non-programmed FG transistor 40a will not be conductive under these conditions. In this fashion, by determining whether a 2T PMOS memory cell 40 is conductive at a voltage below the positive threshold voltage, the state of the binary bit stored by memory cell 40 is also determined.

To provide better programming efficiency and punch-through protection, an n-type region 85 is provided below drain 48 as seen in FIG. 1. The n-type dopant concentration in n region 85 may be approximately 1 to 2 orders of magnitude more concentrated than the n-type dopant concentration in n− well 42. For example, if the concentration of the n-type dopant in n-well 42 is in the high 10¹⁵ to mid 10¹⁶ per cm³, the n-type dopant concentration in n region 85 should be in the mid 10¹⁷ to high 10¹⁸ per cm³. Note that the lateral extent of n region 85 is no greater than the lateral extent of drain 48. By limiting the lateral extent of n region 85 to be no greater than that of drain 48, neither channel 52 nor channel 53 has its dopant concentration affected by n region 85. In this fashion, the threshold voltage for FG transistor 40a and SG transistor 40b is not increased by the presence of n region 85.

Because of the presence of n region 85, the effect on drain 48 is that it resides in a more heavily doped n well. Because of the heavier doping, the dimensions of the depletion region caused by reverse biasing the p-n junction between p+ drain 48 and n region 85 is diminished. However, the same voltage still exists across the depletion region such that the effective electric field within the depletion region is increased. This increased electric field reduces the programming voltage necessary to induce BTBT tunneling of hot electrons through oxide layer 56 into floating gate 54. For example, without the presence of n region 85, drain/source 48 must be reverse biased by approximately −7 to −9 volts with respect to n− well 42. However, by including n region 85, the programming voltage may be dropped to approximately −7 to −5 volts.

Not only does n region 85 lower the programming voltage required for hot electron injection though BTBT tunneling, it also provides punch-through resistance for SG transistor 40b because drain/source 48 acts as source 48 for SG transistor 40b. As just discussed, the effect of n region 85 is such that source 48 resides in a more highly doped n well. In turn, this means that when source 48 is reverse biased with respect to n region 85, the depletion region is smaller. Because punch-through occurs when the depletion region extends across the channel, the shrinking of the depletion region helps protect against punch-through in SG transistor 40b as the dimensions of the memory cell 40 are pushed into the deep submicron region.

Note that n region 85 is not the same as a halo implant. In a halo implant, the source and drain of a MOSFET transistor are each surrounded by an implant of opposite conductivity type to limit lateral diffusion of the source and drain regions. Because a halo implant surrounds both source and drain, it may be denoted as two-sided. In contrast, n region 85 may be thought of as a one-sided implant in that it affects just the drain for FG transistor 40a and just the source for SG transistor 40b. More importantly, n region 85 differs from a traditional halo implant in that n region 85 does not surround drain 48 such that it would affect channel 52 doping. Similarly, channel doping 53 is also not affected. Thus, n region 85 provides the benefits of decreased programming voltage and better punch-through resistance without disadvantageously affecting threshold voltages.

It will be appreciated that the benefits of n region 85 may be enjoyed in other embodiments of a 2T PMOS memory cell embodiments. For example, memory cell 40 requires a double poly process. One layer of polysilicon is used to form floating gate 54 and another layer of poly is used to form select gate 58. However, as described, e.g., in U.S. Pat. No. 5,912,842, the contents of which are hereby incorporated by reference, a 2T PMOS cell may be formed using a single poly process. In this single poly embodiment, the control gate may be formed using a buried P+ diffusion region.

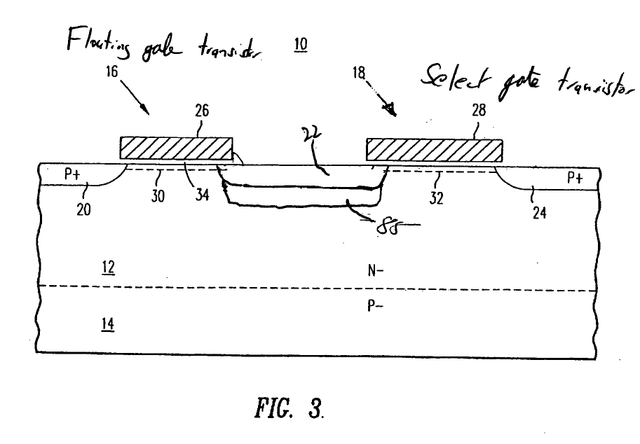

A cross-sectional view of a single poly 2T PMOS cell 10 is shown in FIG. 3. Floating gate transistor 16 and select gate transistor 18 are formed in an n-well region 12 within a p− substrate 14. Floating gate 26, floating gate source 20, drain/source 22 (drain to the floating gate transistor 18 and source to the select gate transistor 16), select gate 28, and select gate drain 24 all function analogously to their counterparts in the double-poly cell 40 of FIG. 1. An n region 85 is placed below drain/source 22 and has the same lateral extent. As such, n region 85 has exactly the same function in a single poly embodiment as it did in a double poly embodiment, namely reducing the programming voltage while providing select gate transistor punch-through resistance. The associated bit line (not illustrated) would couple to select gate transistor drain 24. The associated word line (not illustrated) would couple to select gate 28. Accordingly, an array of single poly 2T PMOS memory cells 10 may be constructed analogously to array 70 discussed with respect to FIG. 2. Thus, to program single poly cell 10, the associated bit line would be pulled down a sufficient amount (e.g., −4 to −9 volts). At the same time, the associated word line would be grounded to make the SG transistor 18 conductive. The end result is to have the P+ source/drain 22 sufficiently reverse biased with respect to n− well 12 so that hot electrons will tunnel into floating gate 26 when the control gate (not illustrated) is pulsed with a positive voltage.

Although the n region 85 provides better programming efficiency and punch-through resistance, it requires only one additional mask and implantation step during fabrication. This minimal fabrication requirement is the same for either a single poly or double poly 2T PMOS cell. For example, with respect to FIG. 3, the fabrication of transistors 16 and 18 may begin by forming n− well 12 and P− substrate 14 by conventional means. After forming tunnel oxide 34 for floating gate transistor 16 and oxide for select gate transistor 18, gates 26 and 28 may be formed using a single layer of polysilicon. Having formed the gates, the n− well 14 may then be implanted with a p-type implant such as boron to form source 20, drain/source 22, and drain 24. No masking steps are necessary for these implants because they will be inherently self-aligned by the presence of gates 26 and 28, which act as masks to prevent doping of the channels 30 and 32. Having implanted the drains and sources, standard masking techniques such as a photoresist mask application may be used to mask off source 20 and drain 24. In addition to masking off source 20 and drain 24, the mask may partially cover gates 26 and 28 as well. Having applied the mask, an n-type dopant such as phosphorus may be implanted to form n region 85. Because gates 26 and 28 act as masks to prevent implantation into channels 34 and 32, the implantation of n region 85 is inherently self-aligned. Moreover, the tolerance or precision required for the implantation mask is quite loose because it must merely cover source 20 and drain 24. The degree to which the implantation mask overlaps the gates 26 and 28 is not critical, thereby making its alignment less time consuming and costly. Because n-type dopants are considerably heavier than a boron implant, those of ordinary skill will appreciate that more implantation energy must be used to form n region 85 than that used to form the source and drains. For example, if drain/source 22 is implanted using 10 to 30 keV, n region 85 may be implanted using 120 to 180 keV. At such implantation energies, P+ drain/source 22 will have a junction depth of approximately 0.1 to 0.25 microns with respect to n region 85. In turn, n region 85 will have a junction depth of approximately 0.2 to 0.5 microns with n-well 12 at these implantation energies.

The formation of n region 85 in a double poly 2T PMOS memory cell requires the same extra masking and implantation step. The implantation mask and implantation steps would be performed after the first poly layer has been formed into gates 54 and 62 as discussed with respect to FIG. 1 and before the second poly layer is used to form control gate 58.

Accordingly, although the invention has been described with respect to particular embodiments, this description is only an example of the invention's application and should not be taken as a limitation. Consequently, the scope of the invention is set forth in the following claims.

1. A two-transistor PMOS memory cell, comprising:
a PMOS select transistor having a drain and a source formed as separate P+ diffusion regions in an N− well;
a PMOS floating gate transistor having a drain and a source formed as separate P+ diffusion regions in the N-well, wherein the P+ diffusion region that forms the floating gate transistor's drain is the same P+ diffusion region that forms the select gate transistor's source; and
an N implant underlying the P+ diffusion region that forms the floating gate transistor's drain.

2. The two-transistor PMOS memory cell of claim 1, wherein the lateral extent of the N implant is substantially the same as the lateral extent of the P+ diffusion region that forms the PMOS floating gate transistor's drain.

3. The two-transistor PMOS memory cell of claim 2, wherein the drain of the PMOS select transistor couples to a bit line of a memory array, and wherein a select gate of the PMOS select transistor couples to a word line of the memory array.

4. The two-transistor PMOS memory cell of claim 2, wherein a floating gate of the PMOS floating gate transistor is formed in a first polysilicon layer, and wherein a control gate of the PMOS floating gate transistor is formed in a second polysilicon layer.

5. The two-transistor PMOS memory cell of claim 2, wherein the memory cell includes a single polysilicon layer containing a floating gate of the PMOS floating gate transistor, and wherein a control gate of the PMOS floating gate transistor is formed as a P+ diffusion region in the N− well.

6. The two-transistor PMOS memory cell of claim 2, wherein the memory cell is configured such that the floating gate transistor may be programmed using band-to-band tunneling.

7. The two-transistor PMOS memory cell of claim 2, wherein the memory cell is configured such that the floating gate transistor may be programmed using Fowler Nordheim tunneling.

8. The two-transistor PMOS memory cell of claim 2, wherein the P+ diffusion region that forms the floating gate transistor's drain has a thickness of approximately 0.1 to 0.25 microns.

9. The two-transistor PMOS memory cell of claim 2, wherein the thickness of the N implant underlying the P+ diffusion region that forms the floating gate transistor's drain is approximately 0.1 to 0.25 microns.

10. A process for manufacturing a two-transistor PMOS memory cell comprising:
forming an N− well in a P− substrate;
forming a tunnel oxide and a select gate channel oxide on a surface of the N− well;
forming a floating gate over the tunnel oxide and a select gate over the select gate channel oxide;
implanting an P-type dopant into the N− well through the floating gate and the select gate to form a first, a second, and a third P+ diffusion region, the second P+ diffusion region located between a first end of the floating gate and a first end of the select gate, the first P+ diffusion region located at an opposite end of the floating gate, and the third P+ diffusion region located at an opposite end of the select gate;
masking the first and third P+ diffusion regions; and
implanting an n-type dopant into the masked N-well region to form an N implant underlying the second P+ diffusion region.

11. The process of claim 10, wherein the process is a single polysilicon layer process, and wherein the act of forming the floating gate and the select gate comprises forming the gates in the single polysilicon layer.

12. The process of claim 10, wherein the process is a double polysilicon layer process, wherein the acto of forming the floating gate and the select gate comprises forming the gates in a first polysilicon layer, the method further comprising:
forming a control gate in a second polysilicon layer.

13. The method of claim 10, further comprising:
forming a bit line and a word line for programming the two-transistor PMOS memory cell.

14. The method of claim 10, further comprising:
manufacturing an array of the two-transistor PMOS memory cells.
